(19) United States
(12) Patent Application Publication
(10) Pub. No.: US 2008/0311295 A1
(43) Pub. Date: Dec. 18, 2008

(54) Film deposition processing apparatus and film deposition processing method

(75) Inventor: Hiroyuki Ode, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/155,362

(22) Filed: Jun. 3, 2008

(30) Foreign Application Priority Data
Jun. 12, 2007 (JP) 2007-154998

(51) Int. Cl. B05D 3/00; C23C 16/00

(52) U.S. Cl. 427/248.1; 118/724

(57) ABSTRACT

A film deposition processing apparatus and a film deposition method for forming a uniform film on a surface of a fine structure formed on a wafer using a supercritical fluid as a medium are provided. Film deposition is performed using a film deposition processing apparatus, comprising: a film deposition processing chamber; a holder which holds the wafer on a top surface inside the film deposition processing chamber; a heater which heats the wafer held on the top surface inside the film deposition processing chamber and is embedded in an upper portion of the film deposition processing chamber; a stirrer which stirs an inside of the film deposition processing chamber; a mixer which prepares a precursor solution made by dissolving at least one of precursors in the supercritical fluid; and a precursor solution inlet which introduces the precursor solution inside the film deposition processing chamber.

### BACKGROUND OF THE INVENTION

1. Field of the Invention

An exemplary aspect of the invention relates to a film deposition processing apparatus and a film deposition method for depositing a uniform film on a surface of a fine structure formed on a wafer using a supercritical fluid as a medium.

2. Description of the Related Art

Film deposition on a surface of a fine structure formed on a wafer is a basic technology demanded in semiconductor device manufacturing processes, such as, film deposition of a capacitor dielectric film, embedding of a Cu wiring layer, and embedding of an STI. In particular, in future, along with advance in miniaturization and high aspect ratio of wafer structure, the importance of the film deposition is expected to increase further. However, it has been gradually difficult to cope with future miniaturization by using existing film deposition technologies (ALD and CVD), thereby use of them is considered to be a cause of decrease of productivity and degradation of yield.

On the other hand, in Japanese Patent Application Laid-Open No. 11-87306, a supercritical drying device, which performs drying a semiconductor substrate after cleaning, etching, or developing for forming a fine pattern by using supercritical fluid, is proposed. The device is equipped with a stirring mean, by which uniform and smooth cleaning, etching, and developing are enabled, and drying without pattern falling can be performed.

Here, since a supercritical fluid has no surface tension as well as has a very low viscosity, it has a rapid substance transport property, thereby enters in a fine structure easily. In other words, if a film deposition technology using a supercritical fluid as a medium is established, it is expected that step coverage surpassing that of an existing film deposition technology can be achieved. For example, as the film deposition technology using supercritical fluid as a medium, a film deposition technology described in Japanese Patent Application Laid-open No. 2003-213425 is suggested.

However, since the apparatus described in Japanese Patent Application Laid-Open No. 11-87306 has a heater for heating a wafer at a lower portion inside a chamber, it is supposed that the following problems will occur if the apparatus is diverted to use for a film deposition processing apparatus.

(1) Since heat always tends to move upward in a supercritical fluid, and under a condition with being stirred, the heat transfer is accelerated further, heat of a processing wafer placed on the heater for heating the wafer disposed at the lower portion of a chamber is easily taken away. As a result, heating of the wafer surface will be significantly difficult and further the temperature on the wafer surface will be caused to have distribution depending on an extent of being stirred. In addition, generally, for a film deposition reaction, a higher temperature than those for cleaning and drying is required.

(2) Flow generated by stirring will accelerate the transport of a precursor onto the surface of the processing wafer. Since there is distribution in strength of stirring imparted on the surface of the processing wafer, the transport rate of the precursor onto the surface of the processing wafer will also have distribution.

Since the apparatus described in Japanese Patent Application Laid-open No. 2003-213425 also has a heater for heating a wafer at the lower portion inside a chamber, not only degradation of heating efficiency but also thermal convection accompanied with upward heat transfer on the wafer surface will occur, resulting in difficulty for supplying a precursor on the wafer surface uniformly.

Therefore, if film deposition processing is performed using the apparatus described in Japanese Patent Application Laid-open Nos. 11-87306 and 2003-213425, transport of wafer temperature and the precursor will have distribution on the wafer surface, and thereby it will be difficult to achieve uniform film deposition. As mentioned above, at the present stage, it is possible to say that such a film deposition technology enabling excellent potential of supercritical fluid to be maximized is not established sufficiently.

### SUMMARY OF THE INVENTION

An exemplary object of the invention is to provide a film deposition processing apparatus and a film deposition method for forming a uniform film on a surface of a fine structure formed on a wafer using a supercritical fluid as a medium.

An exemplary aspect of the invention is a film deposition processing apparatus for forming a film on a surface of a fine structure formed on a wafer using a supercritical fluid as a medium, comprising:
a film deposition processing chamber;
a holder which holds the wafer on a top surface inside the film deposition processing chamber;
a heater which heats the wafer held on the top surface inside the film deposition processing chamber and is embedded in an upper portion of the film deposition processing chamber;
a stirrer which stirs an inside of the film deposition processing chamber;
a mixer which prepares a precursor solution made by dissolving at least one of precursors in the supercritical fluid; and
a precursor solution inlet which introduces the precursor solution inside the film deposition processing chamber.

Moreover, an exemplary aspect of the invention is film deposition processing method for forming a film on the surface of a fine structure formed on a wafer using the above-mentioned film deposition processing apparatus, comprising:
arranging the wafer on a top surface inside a film deposition processing chamber so that a processing surface directs downward;
preparing a precursor solution made by dissolving at least one of precursors in a supercritical fluid inside a mixer;
introducing the precursor solution from a precursor solution inlet inside the film deposition processing chamber;
stirring an inside of the film deposition processing chamber with a stirrer; and
heating the wafer with a heater.

According to the film deposition processing apparatus and the film deposition method of an exemplary aspect of the invention, a uniform film can be formed on a surface of a fine structure formed on a wafer using a supercritical fluid as a medium.

### BRIEF DESCRIPTION OF THE DRAWINGS

FIG. 1 is a conceptual view illustrating the internal structure of a film deposition processing chamber of an exemplary embodiment of the film deposition processing apparatus;

FIG. 2 is a conceptual view illustrating the configuration of an exemplary embodiment of the film deposition processing apparatus; and

FIG. 3 is a conceptual view illustrating the internal structure of a film deposition processing chamber of an exemplary embodiment of the film deposition processing apparatus.

### DETAILED DESCRIPTION OF EXEMPLARY EMBODIMENT

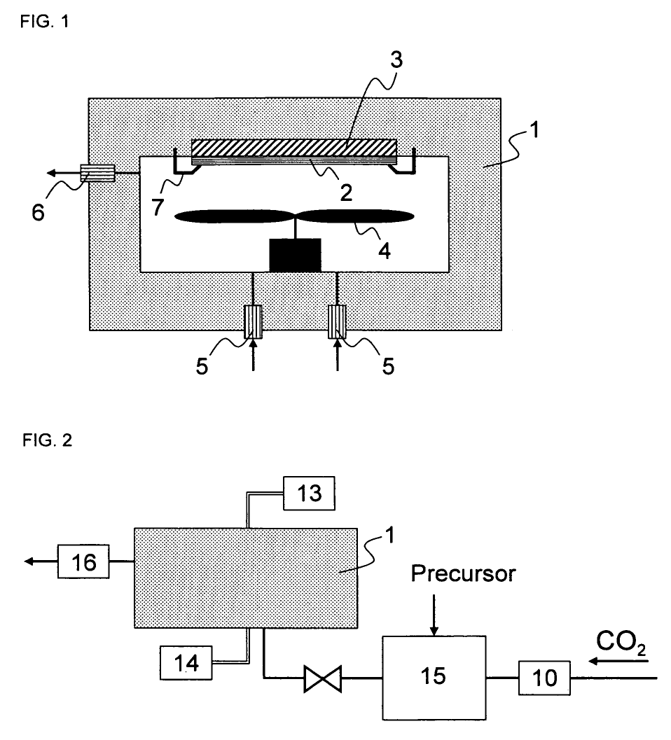

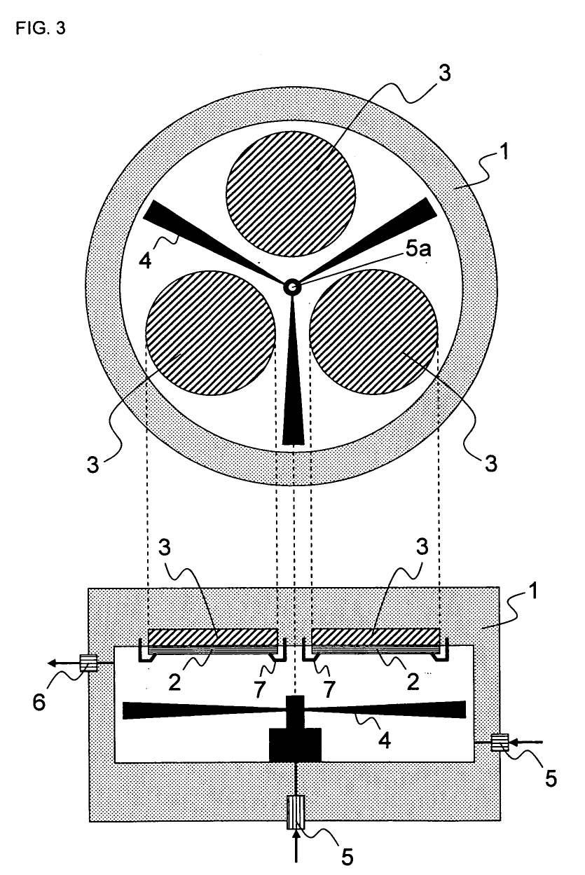

A configuration of an exemplary embodiment of the film deposition processing apparatus is illustrated in FIG. 2, and the internal structure a film deposition processing chamber carried by the film deposition processing apparatus is illustrated in FIG. 1.

A hook 7 as a holder which holds a wafer 2 is disposed inside a film deposition processing chamber 1 that is a high pressure chamber, and, on the top surface inside film deposition processing chamber 1, the wafer 2 is held so that the processing surface directs downward. In order to heat the held wafer 2, a heater 3 is embedded at the upper portion inside film deposition processing chamber 1. From a point of view to heat the wafer 2 uniformly with the heater 3, it is preferable that the heater 3 has a heating surface larger than the surface of the wafer 2, and the wafer 2 is held below the heating surface. The temperature of the heater 3 is controlled by a heater controller 13.

Below the held wafer 2, a propeller 4 as a stirrer is disposed, which can stir the inside of the film deposition processing chamber 1. The rotation speed of the propeller 4 is controlled by a propeller controller 14. In addition, as for the stirrer, although a magnet stirrer may be used, it is preferable for the stirrer to be disposed so as to face to the wafer 2 to be held with each other.

The film deposition processing chamber 1 is equipped with inlets 5 and an outlet 6. To at least one of the inlets 5, a mixer 15 and a solution sending pump 10 are connected, thereby after dissolving at least one of precursors in a supercritical fluid (for example, supercritical carbon dioxide), the resultant precursor solution can be introduced inside the film deposition processing chamber 1. There may be a plurality of the inlet 5, and in this case, each of the inlets 5 may be the inlet which is connected to the mixer 15 and the solution sending pump 10 for introducing the precursor solution, or may be the inlet for directly introducing at least one of precursors. Discharge rate of the outlet 6 is controlled by a back-pressure regulator 16.

When film deposition is performed, first, wafer 2 is placed on the top surface inside the film deposition processing chamber 1 so that the processing surface directs downward, and the wafer 2 is held with the hook 7. Next, the precursor solution in which at least one of precursors is dissolved is prepared inside the mixer 15, and then the precursor solution is introduced inside the film deposition processing chamber 1 from the inlet 5. When there are a plurality of the inlets 5, the precursor solution or the precursor itself is introduced from each of the inlets 5. The introduced precursor solution (or the precursor itself) is stirred by the propeller 4 inside the film deposition processing chamber 1 and made into a homogeneous film deposition processing solution. The wafer 2 is uniformly heated by the heater 3, and a film is formed on the surface of the wafer 2. The film deposition processing solution after film deposition processing is discharged from the outlet 6.

Use of the above-mentioned film deposition processing apparatus enables efficient utilization of stirring effect and uniform film deposition inside the fine structure on the wafer surface. The reason is as follows.

First, in an exemplary embodiment, by focusing attention to that heat always tends to move upward in a supercritical fluid, a heater for heating a wafer is embedded in the upper portion of a film deposition processing chamber and the wafer is held on the top surface inside the film deposition processing chamber. By such a configuration, even under being stirred, heat is caused to remain near the wafer, thereby, temperature distribution on the wafer surface, occurring in an apparatus having the heater for heating the wafer at the lower portion of the film deposition processing chamber, is improved. Therefore, the wafer to be processed can be heated effectively, and the temperature distribution on the wafer surface can be caused to be uniform.

Moreover, with regard to the transport rate of the precursor in a supercritical fluid under being stirred, inventors of an exemplary embodiment experimentally found out that material transport inside fine structure (nanometer order) was hardly affected by flow of such as stirring. The reason of this is considered that although the supercritical fluid is a medium having low viscosity and being sensitive to the effect of flow, Reynolds number decreases more significantly inside the fine structure and the supercritical fluid behaves as if it was a medium having high viscosity and being insensitive to the effect of flow. In other words, while the concentration of the precursor inside the film deposition chamber is caused to be homogeneous instantly by stirring, effect of turbulence due to stirring is not present inside the fine structure.

From the above-mentioned point of view, greater effect of an exemplary embodiment is realized for film deposition on a wafer having the surface on which fine structure is formed than for film deposition on a plane wafer. As for the fine structure, for example, cylinder pores which have a pore diameter of less than 150 nm, and a pore depth of more than 2 μm are included.

The precursor used for film deposition in an exemplary embodiment may be a solid precursor, a liquid precursor, or a gas precursor. When a plurality of precursors are used, all combinations of them may be used. From a point of view in that film deposition is performed by utilizing the property of the supercritical fluid, at least one of the precursors is to be introduced inside the film deposition processing chamber as the precursor solution being dissolved in the supercritical fluid. However, the other precursors may be introduced there by being dissolved in the supercritical fluid, or may be introduced there directly. Moreover, a plurality of the precursors may be introduced by being dissolved in the supercritical fluid, and a mixture of a plurality of the precursors may also be introduced directly. From a point of view in causing the film deposition processing solution inside the film deposition processing chamber to be homogeneous, the solid precursor is preferably introduced by being dissolved in the supercritical fluid. The concentration of the precursor dissolved in the supercritical fluid is arbitrary. Introduction of the precursor solution or the precursor may be continuous or intermittent.

Although, the film deposition processing chamber illustrated in FIG. 1 is a single wafer type chamber in which one wafer is subjected to film deposition processing, a configuration, in which a plurality of holders and heaters are included and a plurality of wafers can be subjected to film deposition processing at the same time, may also be used. As an example, the configuration of a film deposition processing chamber, in which three wafers can be subjected to film deposition processing at the same time, is illustrated in FIG. 3. In addition, in the configuration in FIG. 3, the central shaft of the propeller 4 has a nozzle hole 5a of the inlet 5.

As an example in which a film deposition processing apparatus and a film deposition processing method of an exemplary embodiment are better applied, film deposition inside a fine structure, such as film deposition of a capacitor dielectrics film, embedding of a Cu wiring layer, or embedding of an STI in a semiconductor manufacturing process, is included.

### EXAMPLE

In Example, film deposition of an HfO₂ film was performed on a wafer surface in which capacitor cylinder pores (pore diameter: 150 nm; pore depth: 3 μm) were formed.

Carbon dioxide, which had been heated to a temperature being equal to or greater than the critical temperature (for example, 80° C.), was introduced inside a film deposition processing chamber in the state where a wafer was held on the top surface inside the deposition processing chamber, and the inside of the film deposition processing chamber was pressurized (for example, 10 MPa), and thereby carbon dioxide inside the film deposition processing chamber was caused to be in a supercritical state. Next, by operating a heater for heating a wafer and a stirrer, the wafer was heated to a target film deposition temperature (for example, 300° C.) under a stirred condition. When the wafer temperature became stable, one supercritical carbon dioxide solution, which had been made by dissolving Hf precursor [such as Tetrakis(N-ethyl-N-methylamino)-Hafnium, Tetrakis(1-methoxy-2-methyl-2-propoxy)-Hafnium, or Tetrakis(2,2,6,6-tetramethyl-3,5-heptanedionate)-Hafnium] into supercritical carbon dioxide, and another supercritical carbon dioxide solution, which had been made by dissolving O₂ into supercritical carbon dioxide, were sequentially or simultaneously introduced into the film deposition processing chamber. After an arbitrary introducing time (corresponding to a film deposition time, for example, for 10 minutes), introduction of both of the solution was stopped, and subsequently, by introducing pure supercritical carbon dioxide, precursor and reaction by-products remaining in the film deposition processing chamber were discharged. After the precursor and the reaction by-products inside the film deposition processing chamber were sufficiently discharged, the heater for heating the wafer and stirrer were stopped, and the supercritical carbon dioxide in the film deposition processing chamber was discharged. After depressuring to atmospheric pressure, the film deposition processing chamber was opened and the wafer was taken out. The HfO₂ film formed by such processing had a good coverage property even inside the fine cylinder pores, thereby, a uniform HfO₂ film thickness could be obtained inside the cylinder pores of all evaluation points on the wafer (such as central portion and edge portion of the wafer).

The invention is not limited to the Example.

This application is based upon and claims the benefit of priority from Japanese patent application No. 2007-154998, filed on Jun. 12, 2007, the disclosure of which is incorporated herein in its entirety by reference.

What is claimed is:

1. A film deposition processing apparatus for forming a film on a surface of a fine structure formed on a wafer using a supercritical fluid as a medium, comprising:
a film deposition processing chamber;
a holder which holds the wafer on a top surface inside the film deposition processing chamber;
a heater which heats the wafer held on the top surface inside the film deposition processing chamber and is embedded in an upper portion of the film deposition processing chamber;
a stirrer which stirs an inside of the film deposition processing chamber;
a mixer which prepares a precursor solution made by dissolving at least one of precursors in the supercritical fluid; and
a precursor solution inlet which introduces the precursor solution inside the film deposition processing chamber.

2. The film deposition processing apparatus according to claim 1, wherein the supercritical fluid is supercritical carbon dioxide.

3. The film deposition processing apparatus according to claim 1, comprising a plurality of the precursor solution inlets.

4. The film deposition processing apparatus according to claim 1, comprising a precursor inlet which directly introduces at least one of precursors.

5. The film deposition processing apparatus according to claim 1, comprising a plurality of the holders and a plurality of the heaters, wherein films can be deposited on surfaces of the plurality of wafers simultaneously.

6. A film deposition processing method for forming a film on the surface of a fine structure formed on a wafer using the film deposition processing apparatus according to claim 1, comprising:
arranging the wafer on a top surface inside a film deposition processing chamber so that a processing surface directs downward;
preparing a precursor solution made by dissolving at least one of precursors in a supercritical fluid inside a mixer;
introducing the precursor solution from a precursor solution inlet inside the film deposition processing chamber;
stirring an inside of the film deposition processing chamber with a stirrer; and
heating the wafer with a heater.

7. The film deposition processing method according to claim 6, wherein the supercritical fluid is supercritical carbon dioxide.

8. The film deposition processing method according to claim 6, wherein the film deposition processing apparatus comprises a plurality of the precursor solution inlets.

9. The film deposition processing method according to claim 6, wherein the film deposition processing apparatus comprises a precursor inlet which directly introduces at least one of precursors.

10. The film deposition processing apparatus according to claim 6, wherein the film deposition processing apparatus comprises a plurality of the holders and a plurality of the heaters, wherein films can be deposited on surfaces of the plurality of wafers simultaneously.
